(19) United States
(12) Patent Application Publication
(10) Pub. No.: US 2010/0134154 A1
(43) Pub. Date: Jun. 3, 2010

(54) ODD NUMBER FREQUENCY DIVIDING CIRCUIT

(76) Inventor: Xin He, Weslre (NL)

Correspondence Address: Docket Clerk, P.O. Box 802432, Dallas, TX, 75380, US

(21) Appl. No.: 12/450,629

(22) PCT Filed: Mar. 27, 2008
(86) PCT No.: PCT/IB2008/051149

§ 371 Date: Feb. 4, 2010

(30) Foreign Application Priority Data
Apr. 2, 2007 (EP) 07105481.1

(51) Int. Cl. H03K 21/00

(52) U.S. Cl. 327/115

(57) ABSTRACT

A method and a frequency dividing circuit (1) for dividing a frequency of an input clock signal (CLKᵢₙ) by an odd number to generate an output clock signal (CLKₒᵤₜ) with a lower frequency comprising at least two serially connected edge triggered latches clocked by said input clock signal (CLKᵢₙ), wherein a last edge triggered latch of said serially connected edge triggered latches (4) inverts a triggering direction of a first edge triggered latch (4A) of said serially connected edge triggered latches (4).

### FIELD OF THE INVENTION

The invention relates to an odd number frequency dividing circuit dividing a frequency of an input clock signal by an odd number.

### BACKGROUND OF THE INVENTION

Frequency dividing circuits for dividing a frequency of an input clock signal are well known in the art. A frequency dividing circuit is designed to divide a frequency of a periodic signal by an integer number to achieve a periodic signal with a lower frequency.

The international publication WO2006/051490 A1 describes a device for providing an output signal having a frequency that is obtained by dividing a clock signal frequency by an odd integer. The device comprises a set of latches into which a digital value is shifted based on a clock signal. Each latch of the device is arranged to keep this digital value a predetermined number of half clock cycles, where that digital value is shifted into a following latch delayed with half a clock cycle of the clock signal compared with a previous latch. The device comprises a high number of latches and an external logic.

### OBJECT AND SUMMARY OF THE INVENTION

It is an object of the present invention to provide an odd number frequency dividing circuit comprising a minimum number of latches.

This object is achieved in accordance with the present invention by means of an odd number frequency dividing circuit for dividing a frequency of an input clock signal by an odd number to generate an output clock signal with a lower frequency comprising at least two serially connected edge triggered latches clocked by the input clock signal, wherein a last edge triggered latch of the serially connected latches inverts the triggering direction of a first edge triggered latch of the serially connected latches.

The odd number frequency dividing circuit does not employ any logic besides the serially connected latches. Consequently, the odd number frequency dividing circuit according to the present invention is also superior to conventional frequency dividing circuits in terms of phase noise, power consumption and speed. The number of latches employed by the odd number frequency dividing circuit according to the present invention is minimum, for instance only two latches are necessary for implementing a divide-by-three frequency dividing circuit and only three latches are necessary to provide a divide-by-five frequency dividing circuit. Due to the reduced number of latches and the elimination of external logic the performance with respect to phase noise, speed and power consumption of an odd number frequency dividing circuit according to the present invention is high.

In an embodiment of the odd number frequency dividing circuit according to the present invention an output clock signal is formed by a latched output signal of an edge triggered latch and comprises a 50% duty cycle.

In an embodiment of the odd number frequency dividing circuit according to the present invention each triggered latch comprises a clock input for the input clock signal, a data input for a data signal, an edge control input for an edge control signal, a data output for a latched output signal and an inverted data output of an inverted latched output signal.

In an embodiment of the odd number frequency dividing circuit according to the present invention the clock inputs of the serially connected latches receive a common input clock signal.

In an embodiment of the odd number frequency dividing circuit according to the present invention the clock inputs of the serially connected latches receive a quadrature input clock signal.

In an embodiment of the odd number frequency dividing circuit according to the present invention the output clock signal is a quadrature output clock signal.

In an embodiment of the odd number frequency dividing circuit according to the present invention the data input and the edge control input of the first edge triggered latch are connected to the inverted data output of the last edge triggered latch.

In an embodiment of the odd number frequency dividing circuit according to the present invention each latch being connected between the first edge triggered latch and the last edge triggered latch has a data input connected to the data output of a previous latch and an edge control input connected to an inverted data output of said previous latch.

In an embodiment of the odd number frequency dividing circuit according to the present invention the latches are formed by differential latches.

The invention further provides a method for dividing a frequency of an input clock signal by an odd number, wherein a last edge triggered latch of at least two serially connected edge triggered latches clocked by said input clock signal inverts a triggering direction of a first edge triggered latch of said at least two serially connected edge triggered latches to generate an output clock signal with a lower frequency.

### BRIEF DESCRIPTION OF THE DRAWINGS

The invention will be described in greater detail hereinafter, by way of non-limiting examples, with reference to the embodiments shown in the drawings.

FIG. 1 is a circuit diagram of an exemplary embodiment of an odd number frequency dividing circuit according to the present invention comprising two serially connected latches;

FIG. 2 is a signal diagram showing signals of the embodiment in FIG. 1;

FIG. 3 is a circuit diagram of a further exemplary embodiment of an odd number frequency dividing circuit according to the present invention receiving a quadrature input clock signal;

FIG. 4 is a signal diagram showing signals of the embodiment depicted in FIG. 3;

FIG. 5 is a block diagram of an exemplary embodiment of a direct conversion receiver comprising an odd number frequency dividing circuit according to the present invention;

FIG. 6 is a circuit diagram of a further embodiment of an odd number frequency dividing circuit according to the present invention comprising three serially connected latches;

FIG. 7 is a circuit diagram of a further exemplary embodiment of an odd number frequency dividing circuit according to the present invention having four serially connected latches;

FIG. 8 is a circuit diagram of a further exemplary embodiment of an odd number frequency dividing circuit according to the present invention having two differential latches;

FIG. 9 is a circuit diagram of a further exemplary embodiment of an odd number frequency dividing circuit according to the present invention comprising three differential latches;

FIG. 10 shows an exemplary implementation of a differential edge triggered latch as employed by the embodiments depicted in FIGS. 8, 9;

FIG. 11 shows a further exemplary implementation of a differential edge triggered latch as employed by the embodiments depicted in FIG. 8, 9;

FIG. 12 is a diagram showing a simulated phase noise as generated by the embodiment of an odd number frequency dividing circuit according to the present invention as depicted in FIG. 8;

FIG. 13 is a signal diagram showing a simulated phase noise as generated by the embodiment of an odd number frequency dividing circuit according to the present invention as depicted in FIG. 9.

### DESCRIPTION OF EMBODIMENTS

As can be seen from FIG. 1 an odd number frequency dividing circuit 1 according to the present invention is provided for dividing a frequency of an input clock signal CLKᵢₙ applied to an input terminal 2 of the odd number frequency dividing circuit 1. The frequency of the input signal CLKᵢₙ is divided by an odd number, i.e. an odd integer such as three, five, seven, nine etc., to generate an output signal CLKₒᵤₜ with a lower frequency. The output clock signal CLKₒᵤₜ is output by the odd number frequency dividing circuit 1 at an output terminal 3 as shown in FIG. 1.

The embodiment shown in FIG. 1 divides the frequency of the input clock signal CLKᵢₙ by a factor three. The embodiment shown in FIG. 1 comprises two latches 4A, 4B which are connected in series to each other. The latches 4A, 4B are edge triggered latches which are both clocked by the input clock signal CLKᵢₙ applied to the input terminal 2 of the odd number frequency dividing circuit 1. Each edge triggered latch 4 comprises a clock input 5 for receiving the input clock signal CLKᵢₙ, a data input 6 for a data signal D, an edge control input 7 for receiving an edge control signal Θ, a data output 8 for a latched output signal Q and an inverted data output 9 for an inverted latched output signal Q̅. In the embodiment shown in FIG. 1 the first edge triggered latch 4A comprises a clock input 5A, a data input 6A, an edge control input 7A, a data output 8A and an inverted data output 9A. The second edge triggered latch 4B comprises a clock input 5B, a data input 6B, an edge control input 7B, a data output 8B and an inverted data output 9B. The last edge triggered latch of the serially connected latches 4A, 4B, i.e. the second latch 4B is connected to the first edge triggered latch 4A such that it inverts a triggering direction of the first edge triggered latch 4A for a subsequent clock pulse of the received input clock signal CLKᵢₙ. To achieve this, the data input 6A and the edge control input 7A of the first edge triggered latch 4A are both connected by means of a feedback line 10 to the inverted data output 9B of the last edge triggered latch 4B. A data output such as the data output 8A of the first edge triggered latch 4A is connected via a branch off node 11 and an internal signal line 12 to the output terminal 3 of the odd number frequency dividing circuit 1.

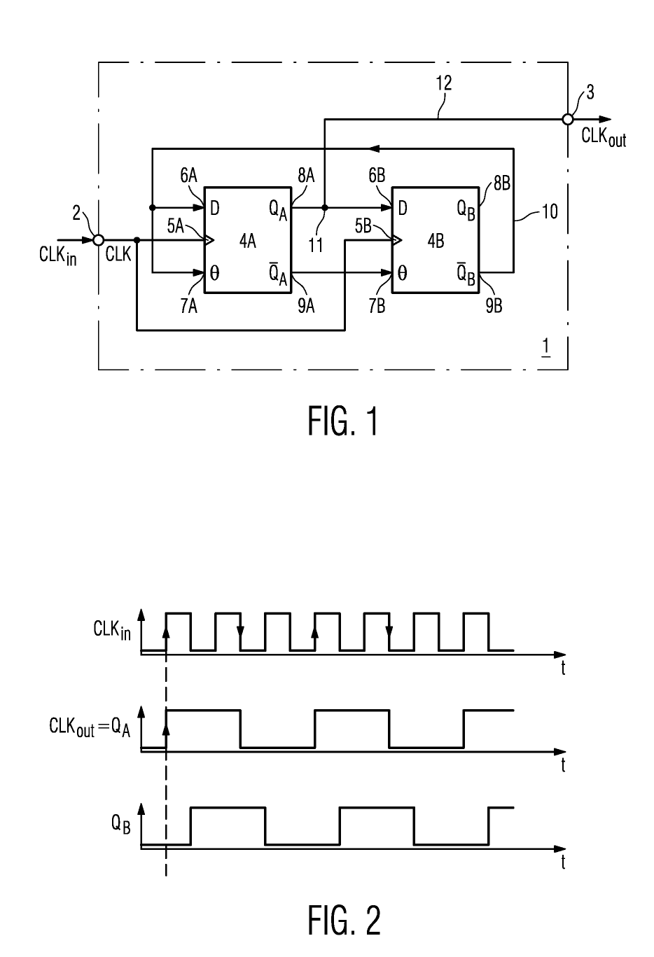

FIG. 2 shows signal diagrams for signals of the embodiment depicted in FIG. 1. The odd number frequency dividing circuit 1 receives an input clock signal CLKᵢₙ. The odd number frequency dividing circuit 1 as shown in FIG. 1 divides the frequency of the input clock signal CLKᵢₙ by a factor three. The output clock signal CLKₒᵤₜ can be formed by the output data signal Q_{A} of the first edge triggered latch 4A as shown in FIG. 2. The frequency of the clock signal CLKₒᵤₜ at the output terminal 3 is lower by a factor three than the frequency of the input clock signal CLKᵢₙ. In the embodiment of FIG. 1 both clock inputs 5A, 5B of the serially connected latches 4A, 4B receive a common input clock signal CLKᵢₙ. As shown in FIG. 2 the odd number frequency dividing circuit 1 comprises two edge triggered latches 4A, 4B to achieve a 50% duty cycle output signal. The duty cycle is the ratio between a pulse duration (τ) and the period T of a periodic signal having a rectangular wave-form. As can be seen from FIG. 1 the data input 6B of the second latch 4B is connected directly with the data output 8A of the first latch 4A. The edge control input 7B of the second latch 4B is connected to the inverted data output 9A of the first latch 4A. The edge control signal Θ applied to the edge control input 7 of a latch 4 is provided to switch a triggering direction of the respective latch, i.e. the triggering direction is inverted. The edge control input 7A of the first edge triggered latch 4A is connected to the data input 6A of this latch 4A, i.e. the latch control input 7A and data input 6A of the first latch 4A receive the same data input at all times. In contrast, the edge control input 7B of the second edge triggered latch 4B is connected to the inverted data output 9A of the first edge triggered latch 4A and the data input 6B of the second edge triggered latch 4B is connected to the data output 8A of the first edge triggered latch 4A so that the edge control input 7B always receives the inverted data in comparison to the data input 6B of the second latch 4B. During operation of the odd number frequency dividing circuit 1 the triggering direction in each latch 4A, 4B is switched between a rising edge as a first triggering direction and a falling edge as a second triggering direction for achieving a division ratio of three.

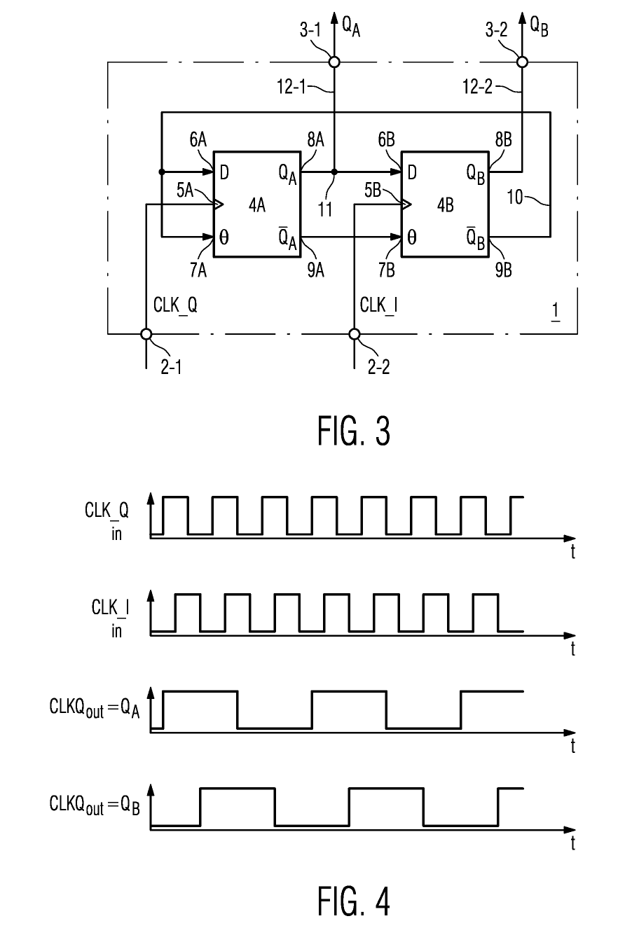

FIG. 3 shows a further exemplary embodiment of an odd number frequency dividing circuit 1 according to the present invention. In this embodiment the clock inputs 5A, 5B of the two serially connected edge triggered latches 4A, 4B receive a quadrature input clock signal via input terminals 2-1, 2-2 of the odd number frequency dividing circuit 1. The output clock signal CLKₒᵤₜ output by the odd number frequency dividing circuit 1 as shown in FIG. 3 is also a quadrature clock signal output at terminals 3-2, 3-3 of the odd number frequency dividing circuit 1. The embodiment shown in FIG. 3 performs a division of the input frequency by a factor three.

FIG. 4 depicts wave-forms of (ideal) signals of the quadrature odd number frequency dividing circuit 1 as shown in FIG. 3. As can be seen the quadrature clock input signal has two signal components which are separated in phase by 90°. The first signal component CLKQᵢₙ of the input clock signal CLKᵢₙ is supplied to terminal 2-1 and the second signal component CLKIᵢₙ of the input clock signal CLKᵢₙ is supplied to the second input terminal 2-2 of the odd number frequency dividing circuit 1 as shown in FIG. 3. The first signal component CLKQₒᵤₜ of the quadrature output clock signal output at terminal 3-1 is depicted as data output signal Q_{A} of the first latch 4A and the second signal component CLKIₒᵤₜ of the quadrature output clock signal CLKₒᵤₜ is output at terminal 3-2 connected to the data output 8B of the second edge triggered latch 4B.

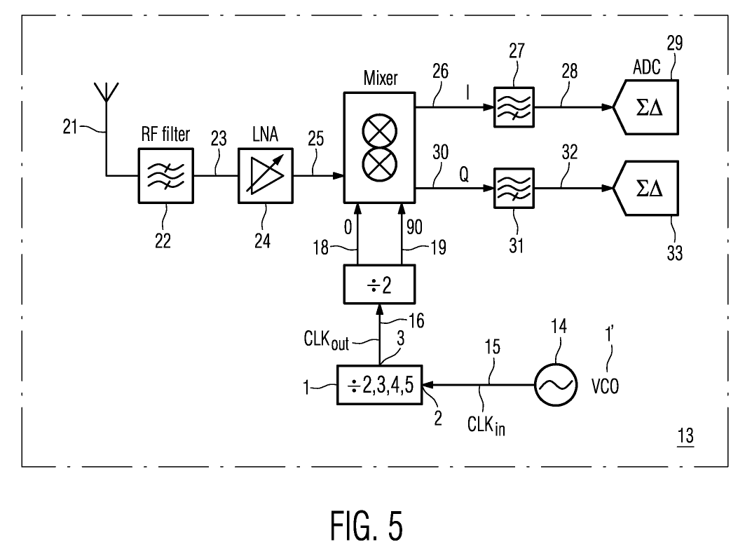

FIG. 5 shows an exemplary embodiment of a direct conversion receiver 13 comprising an odd number frequency dividing circuit 1 according to the present invention. In a multimode apparatus such as a multimode phone a single transceiver has to cope with multiple wireless standards thus requiring multiple local oscillators (LO) to handle signals for different frequency bands. To reduce the number of coils in LO-generation and hence the necessary chip area the receiver 13 as shown in FIG. 5 uses a single voltage controlled oscillator 14 (VCO) with a large tuning range to cover several frequency bands after frequency division. The voltage controlled oscillator 14 is controlled by an input voltage. The frequency of oscillating signal is varied with the applied DC input voltage. The generated oscillating signal is supplied via a signal line 15 to the input terminal 2 of the odd number frequency dividing circuit 1 according to the present invention. The output terminal 3 of the odd number frequency dividing circuit 1 is connected via a signal line 16 to a divide-by-two circuit 17 to obtain a quadrature output clock signal supplied via a signal lines 18, 19 to a mixer 20 of the receiver 13. The receiver 3 further comprises a reception antenna 25 connected to a band pass filter 22. The band pass filter 22 is connected via a signal line 23 to a low noise amplifier 24 (LNA) with adjustable gain amplifying the received and filtered signal. The output of the low noise amplifier 24 is connected via a signal line 25 to the mixer 20 which generates an inphase signal component I and a quadrature signal component Q by mixing the amplified input signal with the quadrature clock signal supplied to the mixer 20 via lines 18, 19. The in-phase signal component I is applied via a signal line 26 to a low pass filter 27 supplying the low passed filtered in-phase signal component I via a signal line 28 to a first sigma-delta-analog-digital converter 29. The quadrature signal component Q output by the mixer 20 is applied via a signal line 30 to a low pass filter 31 which outputs the low pass filtered quadrature signal component Q via a signal line 32 to a second sigma-delta-analog-digital converter 33.

The odd number frequency dividing circuit 1 according to the present invention as shown in FIG. 1 performing a division by a factor three can be extended to other odd number frequency dividers having a 50% duty cycle.

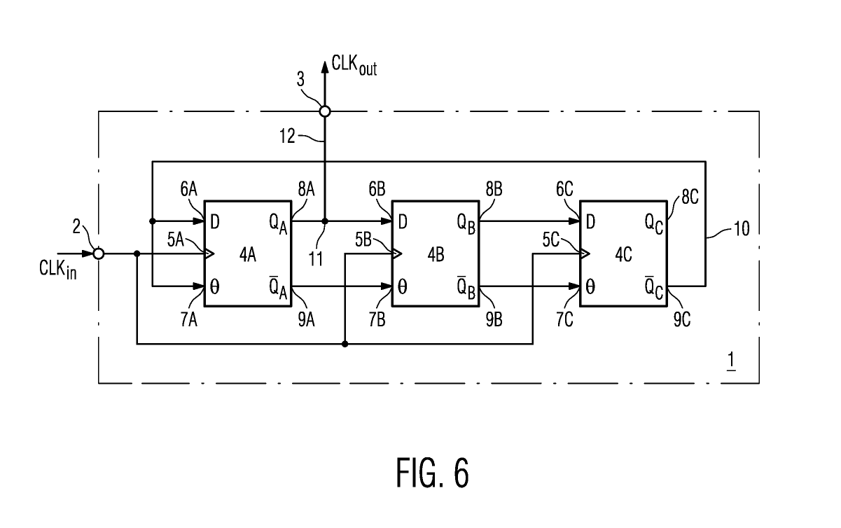

FIG. 6 shows an embodiment of the odd number frequency dividing circuit 1 performing a division of the input clock signal frequency by a factor five. The odd number frequency dividing circuit 1 as shown in FIG. 6 employs three edge triggered latches 4A, 4B, 4C. The last serially connected latch 4C inverts the triggering direction of the first edge triggered latch 4A for instance for each clock pulse of the input clock signal CLKᵢₙ supplied to the terminal 2 of the frequency dividing circuit 1. In the embodiment shown in FIG. 6 each clock input 5A, 5B, 5C of the serially connected latches 4A, 4B, 4C receives a common input clock signal CLKᵢₙ. The inverted data output 9C of the last edge triggered latch 4C is connected to the data input 6A and the edge control input 7A of the first edge triggered latch 4A via a feedback line 10. An intermediate edge triggered latch 4B being connected between the first edge triggered latch 4A and the last edge triggered latch 4C has a data input 6B being connected to the data output 8A of the previous latch 4A. The edge control input 7B of the intermediate edge triggered latch 4B is connected to the inverted data output 9A of the previous latch 4A.

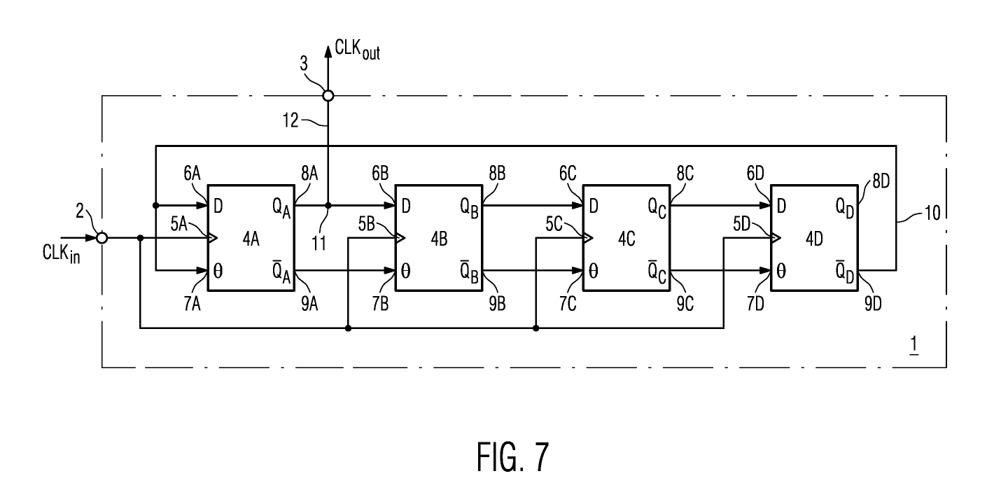

FIG. 7 shows a further embodiment of the odd number frequency dividing circuit 1 according to the present invention performing a division of the input clock frequency by a factor seven. The embodiment shown in FIG. 7 comprises four edge triggered latches 4A, 4B, 4C, 4D.

The odd number frequency dividing circuit 1 according to the present invention can be extended to more latches for any desired odd division factor. As can be seen from the embodiments depicted in FIG. 3, 6, 7 the division factor provided by the odd number frequency dividing circuit 1 according to the present invention depends on the number of the serially connected edge triggered latches 4 as following:

Division factor=number of latches·2−1.

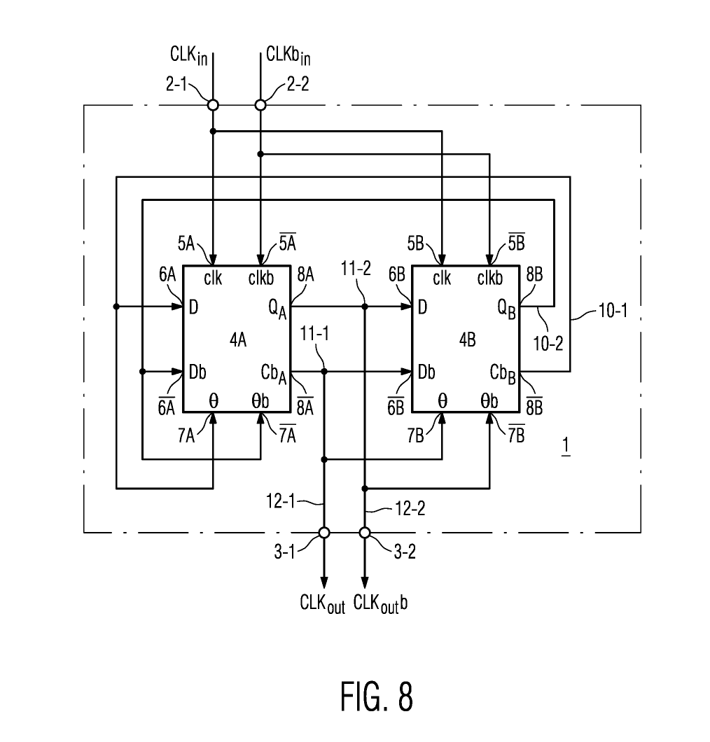

FIG. 8 shows a differential implementation of an odd number frequency dividing circuit 1 having a division factor three.

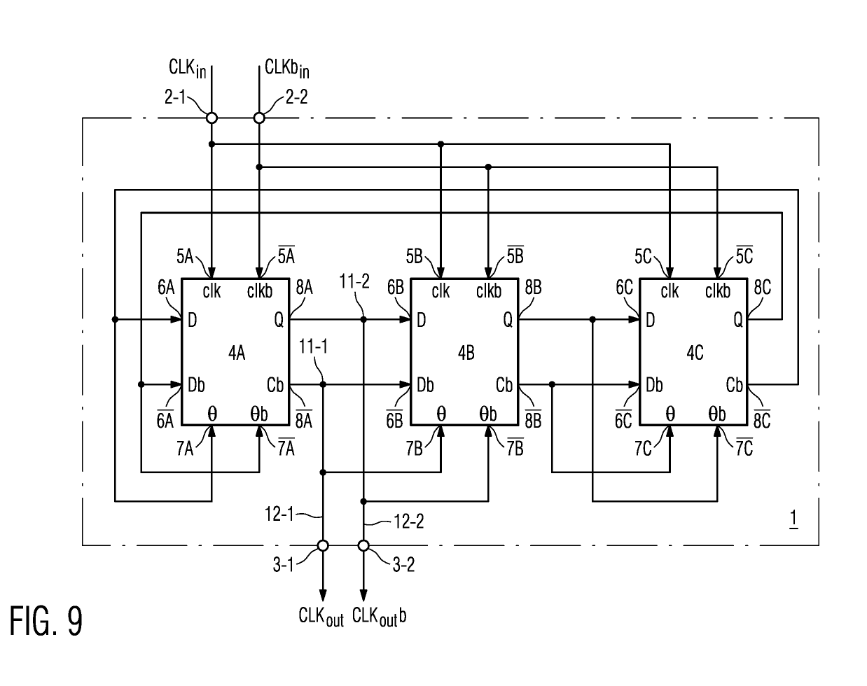

FIG. 9 shows a differential implementation of an odd number frequency dividing circuit 1 according to the present invention performing a frequency division by a factor five. Since all signals are differential, all signal loads can be set symmetrically so that the output clock signal CLKₒᵤₜ has in any case a 50% duty cycle.

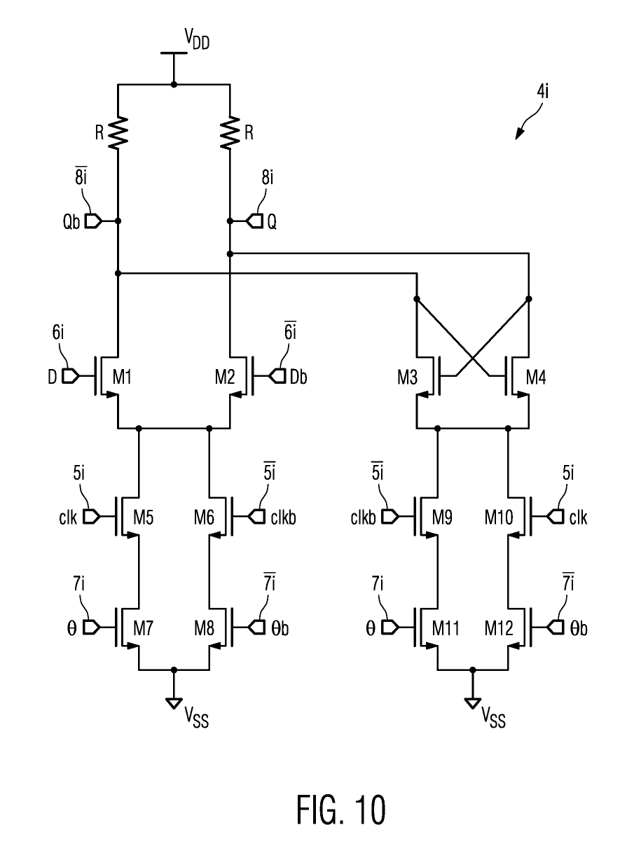

FIG. 10 shows a possible CMOS implementation of a differential edge controlled latch 4 as employed by the differential embodiments of the odd number frequency dividing circuit I depicted in FIGS. 8, 9. The exemplary embodiment shown in FIG. 10 shows a CMOS implementation comprising CMOS-FETS. The edge triggered latch 4-i as shown in FIG. 10 comprises twelve NMOS transistors M1 to M12. The NMOS transistors M1 to M2 are provided for data sampling while cross coupled NMOS transistors M3, M4 hold the sampled data. NMOS transistors M5, M6, M7, M8 form an ON-OFF-control switch and NMOS transistors M9 to M12 form a current source.

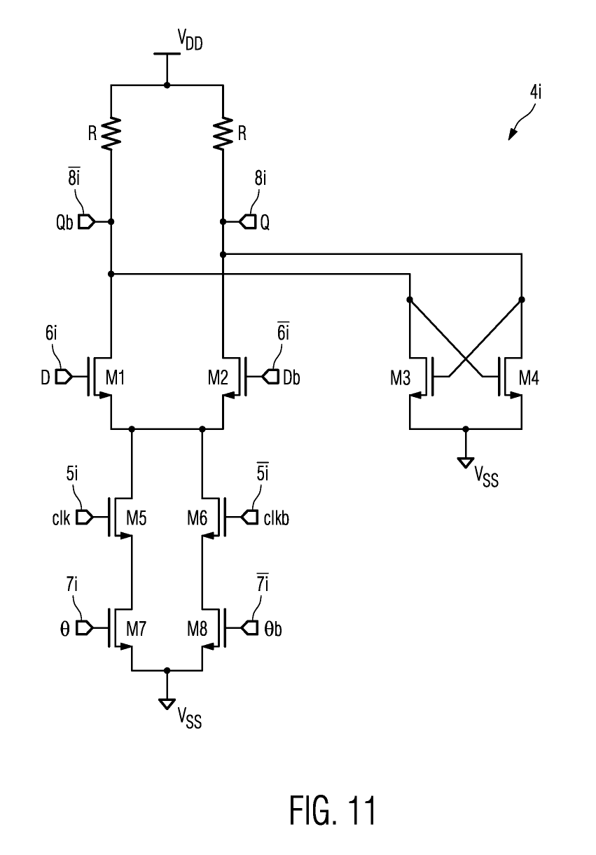

In the embodiment shown in FIG. 11 the current source is removed to save driving buffer size and to diminish power consumption. In the embodiment of the differential edge triggered latch 4-i shown in FIG. 11 the cross-coupled NMOS transistors M3, M4 are connected directly to ground.

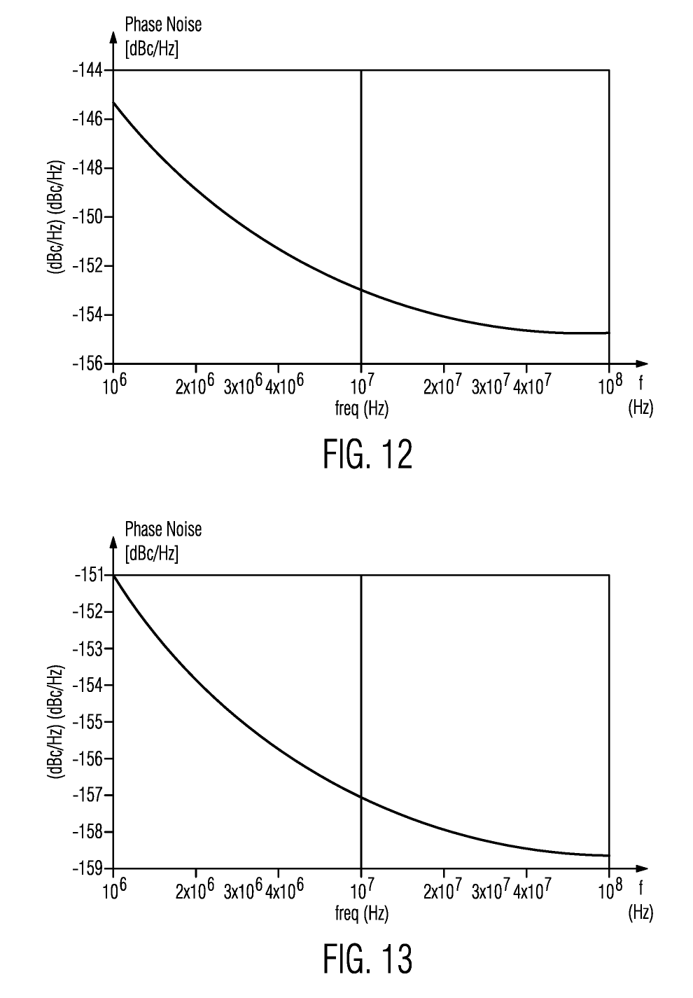

FIG. 12 shows a diagram of a simulated phase noise of a divide-by-three odd number frequency dividing circuit 1 which has a 50% duty cycle output as depicted by the embodiment of FIG. 8. The input clock signal has a frequency of 10 GHz. The current consumption is 1.8 mA with a 1.2 V supply voltage in a 90 nm CMOS implementation.

FIG. 13 shows a diagram of a simulated phase noise of a divide-by-five odd number frequency dividing circuit 1 as depicted in the embodiment of FIG. 9. The frequency of the input clock signal is 8 GHz and the current consumption is 2.7 mA with a 1.2 V supply voltage in a 90 nm CMOS implementation.

The odd number frequency dividing circuit 1 for dividing a frequency of an input clock signal by an odd number to generate an output signal with a lower frequency generates an output signal with a 50% duty cycle. In case that the input clock signal is quadrature it is also possible to obtain a quadrature output clock signal. The number of latches 4 employed by the odd number frequency dividing circuit 1 according to the present invention is minimized and external logic other than the employed latches 4 is not necessary. Because of the minimized number of latches 4 the odd number frequency dividing circuit 1 according to the present invention is superior in terms of phase noise performance, speed and power consumption. The odd number frequency dividing circuit 1 can divide any periodic signal by any odd integer. The odd number frequency dividing circuit 1 according to the present invention can for example be applied for local oscillating frequency generation, for instance in a multimode receiver coping with multiple frequency bands. In particular, combined by two, divide-by-four and divide-by-three/five dividing circuits significantly reduce the tuning range of a voltage controlled oscillator (VCO) as needed for example in DVB-H and DVB-T receivers.

Finally, it should be noted that the aforementioned embodiments illustrate rather than limit the invention, and that those skilled in the art will be capable of designing many alternative embodiments without departing from the scope of the invention as defined by the appended claims. In the claims any reference signs placed in parentheses shall not be construed as limiting the claims. The words “comprising” and “comprises” and the like, will not exclude the presence of elements or steps other than those listed in any claim or the specification as a whole. The singular reference of an element does not exclude the plural reference of such elements and vice versa. In an apparatus claim enumerating several means, several of these means may be embodied by one and the same item of software or hardware. The mere fact that certain measures are recited in mutually different independent claims does not indicate that a combination of these measures can be used to advantage.

1. An odd number frequency dividing circuit for dividing a frequency of an input clock signal by an odd number to generate an output clock signal with a lower frequency comprising at least two serially connected edge triggered latches clocked by said input clock signal, wherein the last edge triggered latch of said serially connected latches inverts a triggering direction of the first edge triggered latch of said serially connected edge triggered latches.

2. The odd number frequency dividing circuit according to claim 1, wherein said output clock signal is formed by a latched output signal of an edge triggered latch and comprises a 50% duty cycle.

3. The odd number frequency dividing circuit according to claims 1, wherein each edge triggered latch comprises:
a clock input for said input clock signal,
a data input for a data signal,
an edge control input for an edge control signal,
a data output for a latched output signal, and
an inverted data output for an inverted latched output signal.

4. The odd number frequency dividing circuit according to claim 3, wherein said clock inputs of said serially connected edge triggered latches receive a common input clock signal.

5. The odd number frequency dividing circuit according to claim 3, wherein the clock inputs of said serially connected edge triggered latches receive a quadrature input clock signal.

6. The odd number frequency dividing circuit according to claim 5, wherein the output clock signal is a quadrature output clock signal.

7. The odd number frequency dividing circuit according to claim 3, wherein the data input and the edge control input of the first edge triggered latch are connected to the inverted data output of the last edge triggered latch.

8. The odd number frequency dividing circuit according to claim 7, wherein each edge triggered latch being connected between said first edge triggered latch and said last edge triggered latch has a data input connected to a data output of a previous edge triggered latch and an edge control input connected to an inverted data output of said previous edge triggered latch.

9. The odd number frequency dividing circuit according to claim 1, wherein the edge triggered latches are differential latches.

10. A method for dividing a frequency of an input clock signal by an odd number, wherein a last edge triggered latch of at least two serially connected edge triggered latches clocked by said input clock signal inverts a triggering direction of a first edge triggered latch of said at least two serially connected edge triggered latches to generate an output clock signal with a lower frequency.
